(19) United States
(12) Patent Application Publication
(10) Pub. No.: US 2010/0108116 A1
(43) Pub. Date: May 6, 2010

(54) Enhanced Dye Sensitized Solar Cells

(75) Inventors: Minoru Taya, Mercer Island, WA (US); Hee Seok Kim, Seattle, WA (US); Miseon Choi, Seattle, WA (US); Morio Nagata, Toyota (JP)

Correspondence Address: LAW OFFICES OF RONALD M ANDERSON, 600 108TH AVE, NE, SUITE 507, BELLEVUE, WA, 98004, US

(73) Assignee: University of Washington, Seattle, WA (US)

(21) Appl. No.: 12/534,517

(22) Filed: Aug. 3, 2009

Related U.S. Application Data
(60) Provisional application No. 61/085,732, filed on Aug. 1, 2008.

(51) Int. Cl. H01L 35/14; H01L 31/00; B22F 3/105

(52) U.S. Cl. 136/239; 136/256; 419/1

(57) ABSTRACT

A first concept is directed to an improved dye-sensitized solar cell (DSSC). In a first embodiment, photo energy conversion efficiency (PCE) is increased by employing a reflective layer disposed underneath the DSSC device to direct light that would otherwise be wasted back into the DSSC device. In a second embodiment, the PCE of a DSSC is increased by adding an additional dye, which exhibits significant absorption in the red and near-IR regions. A novel phthalocyanine derivative has been developed that absorbs well in the red and near IR-regions, readily couples to the titanium oxide semiconductor in the DSSC, and enables the DSSC device to exhibit a high photo-current efficiency. A second concept is directed to novel thermoelectric materials formed from a mechanical alloy of silicon and at least one other periodic element, wherein the mechanical alloy is fused together using spark plasma sintering.

### RELATED APPLICATIONS

This application is based on a prior copending provisional application Ser. No. 61/085,732, filed on Aug. 1, 2008, the benefit of the filing data of which is hereby claimed under 35 U.S.C. §119(e).

### GOVERNMENT RIGHTS

This invention was made with U.S. government support under Grant No. FA 9550-06-01-0326 awarded by the Air Force Office of Scientific Research (AFOSR). The U.S. government has certain rights in the invention.

### BACKGROUND

World wide demand for petroleum is increasing. It would be desirable to provide alternative energy technologies.

For example, it would be desirable to provide improved solar cell technology, particularly where the technology is based on relatively low cost manufacturing techniques.

It would further be desirable to provide improved energy harvesting techniques, to extract energy from waste heat.

### SUMMARY

This application specifically incorporates by reference the disclosures and drawings of each patent application identified above as a related application.

A first aspect of the concepts disclosed herein is directed to an improved dye-sensitized solar cell (DSSC).

In a first exemplary embodiment, a photo energy conversion efficiency (PCE) of a DSSC is increased by employing a substantially transparent electrolyte, a substantially transparent substrate supporting the electrolyte, and a reflective layer disposed underneath the DSSC device to direct light that would otherwise be wasted, back into the DSSC device.

In a second embodiment, the PCE of a DSSC is increased by adding an additional dye, which exhibits significant absorption in the red and near infra-red (IR) regions. A novel phthalocyanine derivative has been developed, which absorbs well in the red and near IR-regions, and which readily couples to the titanium oxide semiconductor in the DSSC, thus enabling the DSSC device to exhibit a high photo-current efficiency.

A second aspect of the concepts disclosed herein is the identification of thermal electric materials, including Mg2Si, which can be used to harvest energy from waste heat in a variety of environments.

This Summary has been provided to introduce a few concepts in a simplified form that are further described in detail below in the Description. However, this Summary is not intended to identify key or essential features of the claimed subject matter, nor is it intended to be used as an aid in determining the scope of the claimed subject matter.

### DRAWINGS

Various aspects and attendant advantages of one or more exemplary embodiments and modifications thereto will become more readily appreciated as the same becomes better understood by reference to the following detailed description, when taken in conjunction with the accompanying drawings, wherein:

FIG. 1A schematically illustrates operational principles of a PRIOR ART DSSC;

FIG. 1B schematically illustrates operational principles of an exemplary improved DSSC implementing many of the concepts disclosed herein;

FIG. 2A graphically illustrates a current versus voltage curve for an exemplary glass-based DSSC specimen 4×4 mm² in size, which includes both an anti-reflecting upper layer and a reflective bottom layer;

FIG. 2B schematically illustrates the glass-based DSSC whose current versus voltage curve is shown in FIG. 2A;

FIG. 3A graphically illustrates a current versus voltage curve of an exemplary DSSC specimen employing a flexible substrate (a platinum coated polyethylene terephthalate (PET) film), the specimen having a size of 4×4 mm²;

FIG. 3B schematically illustrates the flexible substrate-based DSSC, whose current versus voltage curve is shown in FIG. 3A, being flexed;

FIG. 4A graphically illustrates an incident photon-to-photo current efficiency (IPCE) curve of a DSSC device including a modified phthalocyanine-based dye;

FIG. 4B schematically illustrates an exemplary phthalocyanine-based dye; and

FIG. 5 schematically illustrates a DSSC including two different dye sensitizers incorporated into two different working layers, so that charge interactions between the different dye sensitizers do not impair operation of the solar cell.

### DESCRIPTION

### Figures and Disclosed Embodiments are not Limiting

Exemplary embodiments are illustrated in referenced Figures of the drawings. It is intended that the embodiments and Figures disclosed herein are to be considered illustrative rather than restrictive. No limitation on the scope of the technology and of the claims that follow is to be imputed to the examples shown in the drawings and discussed herein.

Some of the Figures schematically illustrate exemplary DSSCs, enabling different layers of the DSSCs to be visualized. It should be recognized that the relative dimensions of each layer are not intended to be limiting, and the concepts disclosed herein encompass DSSCs having similar layers of different relative dimensions.

### Improved DSSC Devices

Disclosed herein are several improved DSSCs, which employ either rigid transparent substrates (such as glass) or flexible transparent substrates (such as polymers). An exemplary flexible substrate is a platinum-coated PET film, which can be employed as a counter electrode. Other useful transparent conductive flexible substrates include polymers coated with an indium tin oxide (ITO) layer. While ITO represents an exemplary conductive coating, it should be recognized that other conductive coatings can be employed. In many embodiments, generally transparent coatings are preferred; however, it should be understood that in some embodiments, an opaque bottom counter electrode is acceptable, if a reflective layer will not be disposed below the bottom counter electrode.

In empirical studies, PCEs of about 6% were observed for the improved DSSC devices disclosed herein. If one calculates the PCE/weight, one can define the specific energy conversion efficiency (SECE) of a DSSC. The SECE of higher density devices will be lower than the SECE of lower density devices. The SECE of empirical glass-based DSSC devices disclosed herein was determined to be about 66% (cm²/g), while the SECE of the empirical flexible substrate DSSC devices disclosed herein was determined to be about 660% (cm²/g). Clearly, the flexible DSSC devices offer advantages in applications where the weight penalty is high, such as an airplane or spacecraft. Thus, one aspect of the concepts disclosed herein is the incorporation of the improved DSSC devices based on transparent flexible substrates into an airplane, a remotely piloted vehicle (RPV), an unmanned aerial vehicle (UAV), or a spacecraft.

Inorganic-based solar cells generally exhibit a relatively good conversion efficiency, but they are generally expensive, difficult to manufacture, heavy and bulky, utilize toxic materials, and have limited scalability due to their lack of a large flexible area. The conversion efficiency of prior art dye-sensitized solar cells (DSSC) is still relatively low. However, DSSCs are relatively low-cost, light weight, employ relatively less toxic materials, and are more readily scalable.

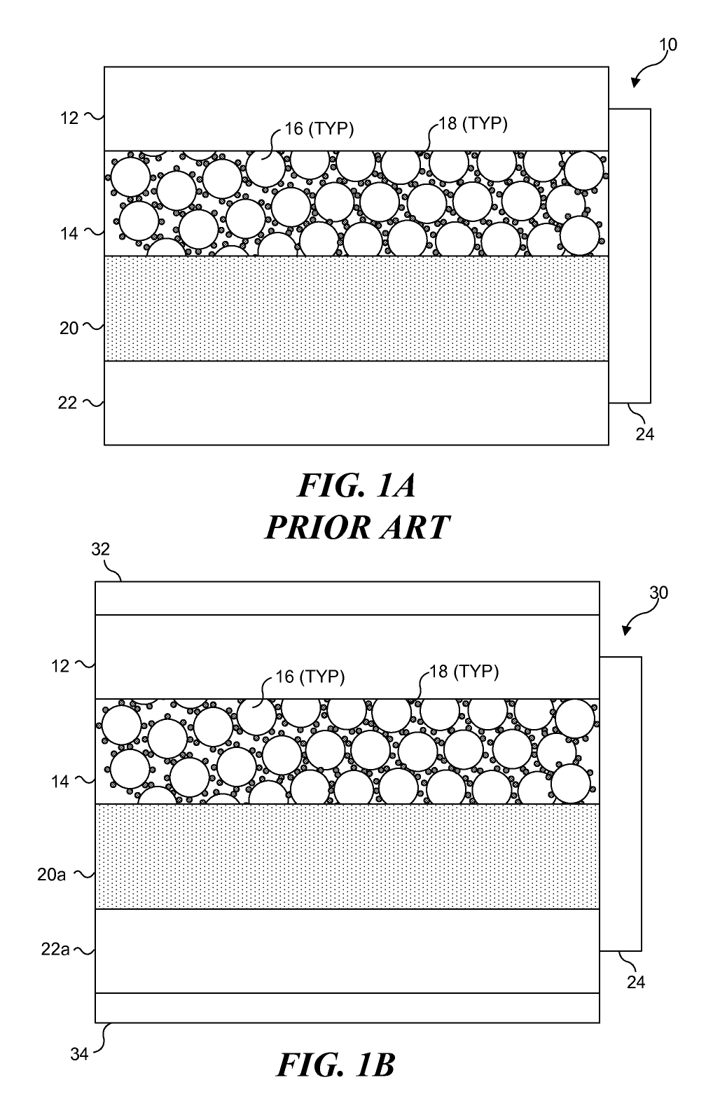

Conventional DSSCs include five major parts, a nano crystalline titanium oxide (TiO₂) semiconductor film, a dye sensitizer, a redox electrolyte, a counter electrode (generally platinum (Pt)), and a transparent conductive substrate. FIG. 1A schematically illustrates operational principles of a prior art DSSC 10. An upper layer of DSSC 10 is a transparent conductive substrate 12 (generally glass, with a conductive coating such an indium tin oxide (ITO) or fluorine-doped tin oxide (SnO₂:F)). Photons enter the DSSC cell through transparent conductive substrate 12. A working layer 14 includes a plurality of titanium oxide (TiO₂) semiconductor particles 16, with each particle coated with molecules 18 of a dye sensitizer. The TiO₂ particles are arranged in a porous nano crystalline lattice (referred to as a “film”). The TiO₂ film is generally soaked in a solution of the dye sensitizer (generally a ruthenium-based dye) to coat the TiO₂ particles with molecules of the dye sensitizer (sometimes separate semiconductor and dye layers are employed, rather than the mixed layer shown in the Figure; noting that the improved DSSCs disclosed herein are discussed in terms of a working layer in which the semiconductor and dye are combined in a single layer, but if desired separate layers could be employed, so long as electrons ejected from the dye layer can diffuse into the semiconductor layer). An electrolyte layer 20 (generally iodine/tri-iodide) is disposed between working layer 14 and a lower counter electrode layer 22 (which is electrically coupled to transparent conductive substrate 12 via a conductor 24).

Photons pass through transparent conductive substrate 12 and enter the working layer. Some photons encounter molecules of the dye sensitizer, exciting these molecules and causing the excited molecules to eject an electron. The ejected electrons dissipate through the working layer into the transparent conductive substrate 12. The electrolyte layer provides replacement electrons to the previously excited molecules of the dye sensitizer, and the counter electrode acquires replacement electrons from transparent conductive substrate 12 via conductor 24. The lower counter electrode layer does not need to be transparent.

The exemplary improved DSSC devices disclosed herein include one or more of the following elements: (1) a transparent counter electrode layer coupled to a reflective surface, enabling photons that pass through the DSSC to be reflected back into the DSSC to excite additional dye molecules; (2) a coating for the upper transparent conductive substrate to enable the DSSC to capture oblique rays of light, which otherwise would be reflected off the upper transparent conductive substrate (and not pass through the transparent conductive substrate); (3) the use of flexible transparent conductive substrates (for the upper electrode and the lower counter electrode) to enable the DSSC to conform to surfaces; (4) the use of an additional dye sensitizer that interacts with IR and red light, and an additional electrode; and, (5) the use of an electrolyte that remains functional at relatively low temperatures. It should be understood that the novel concepts disclosed herein encompass DSSC embodiments that include any combination and permutation of the above elements, including embodiments implementing only one of the above elements.

FIG. 1B schematically illustrates an exemplary DSSC 30 including some of the improvements noted above. DSSC 30 also includes upper transparent conductive substrate 12; however, the upper (i.e., outer) surface of the conductive substrate is coated with a material 32 enabling oblique light rays to be directed into the DSSC, rather than reflecting off the transparent conductive substrate 12. The selection of the material is a function of the refractive index of the transparent conductive substrate. Where glass is used for the transparent conductive substrate, magnesium fluoride represents a reasonable coating. In general, the refractive index of the coating material should approximate the square root of the refractive index of the transparent conductive substrate. Such coating materials are normally effective at reducing reflections at smaller angles of incidence, as well as reducing the reflection of light striking the coating at more oblique angles.

DSSC 30 also includes working layer 14, comprising the plurality of titanium oxide (TiO₂) semiconductor particles 16 coated with molecules 18 of the dye sensitizer. An electrolyte layer 20a is not based on the conventional iodine/tri-iodide electrolyte, but instead, employs an electrolyte material that remains functional at relatively low temperatures, so that the DSSC can be used in a wide range of environmental conditions. As noted above, one aspect of the concepts disclosed herein is to provide DSSCs that can be used in aviation applications, and temperatures at higher altitudes can drop as low as −50 degrees F.

Referring once again to FIG. 1B, a lower counter electrode layer 22a (which is electrically coupled to transparent conductive substrate 12 via a conductor 24) is also formed from a transparent conductive substrate, such that photons passing through lower counter electrode layer 22a bounce off a reflective layer 34, and are directed back into the DSSC, to interact with the dye sensitizer molecules, generally as discussed above.

With respect to the dye sensitizer, ruthenium-based dyes are conventionally employed, and such dyes can harvest the photon energy for the visible light region. The PCE of such a device can be significantly increased (to more than 10%) by employing the upper anti-scattering or anti-reflecting layer, and the lower reflecting layer of DSSC 30, to increase the number of photons entering the device.

Note that DSSC 30 of FIG. 1B includes the following additional elements, compared to the prior art DSSC of FIG. 1A: (1) a transparent counter electrode layer coupled to a reflective surface, enabling photons that pass through the DSSC to be reflected back into the DSSC to excite additional dye molecules; (2) a coating for the upper transparent conductive substrate to enable the DSSC to capture oblique rays of light, which otherwise would be reflected off of the upper transparent conductive substrate; and (3) the use of an electrolyte that is functional in relatively low temperatures. It should be understood that the concepts disclosed herein encompass other DSSC embodiments that include any combination of such elements, including the implementation of only a single such element. If desired, a flexible transparent conductive substrate (such as PET with a conductive coating) can be employed for the upper transparent conductive substrate and the lower counter electrode layer, to enable the resulting DSSC to be implemented as a lighter weight device (PET being lighter than glass). Furthermore, the use of PET in such layers will result in a flexible DSSC that can conform to a surface, such as the curving surface on a wing of an aircraft.

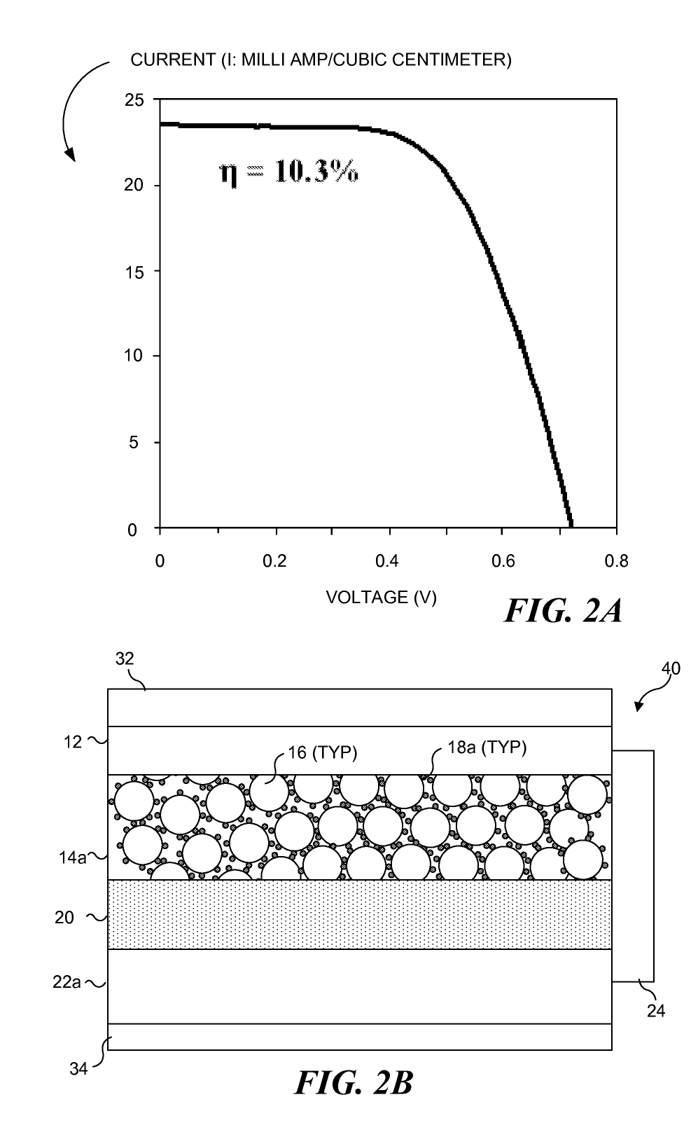

FIG. 2A graphically illustrates a current versus voltage curve of a glass-based DSSC specimen (4×4 mm² in size), which includes both an upper anti-reflecting coating, and a lower reflection layer, generally as discussed above. That DSSC specimen also includes a novel red dye, for interacting with red and near IR light. Ruthenium-based dyes in prior art DSSCs do not interact with red and near IR light. FIG. 2B schematically illustrates the glass-based DSSC specimen whose current versus voltage curve is shown in FIG. 2A.

Referring to FIG. 2B, a DSSC 40 also includes a glass-based upper transparent conductive substrate 12 similarly coated with anti-reflective material 32. DSSC 40 also includes working layer 14a, comprising the plurality of titanium oxide (TiO₂) semiconductor particles 16 coated with molecules 18a of the novel red dye sensitizer. A conventional iodide/tri-iodide electrolyte layer 20 was employed. DSSC 40 further includes a glass-based lower counter electrode layer 22 (which is electrically coupled to transparent conductive substrate 12 via a conductor 24), and reflective layer 34, so that photons passing through lower counter electrode layer 22 bounce off the reflective layer and are directed back into the DSSC, to interact with the dye sensitizer molecules, generally as discussed above. It should be understood that the concepts disclosed herein also encompass DSSCs comprising the novel red dye that employ a different electrolyte, and which lack one or more of the top anti-reflective coating or the lower reflective layer, and combinations and permutations thereof.

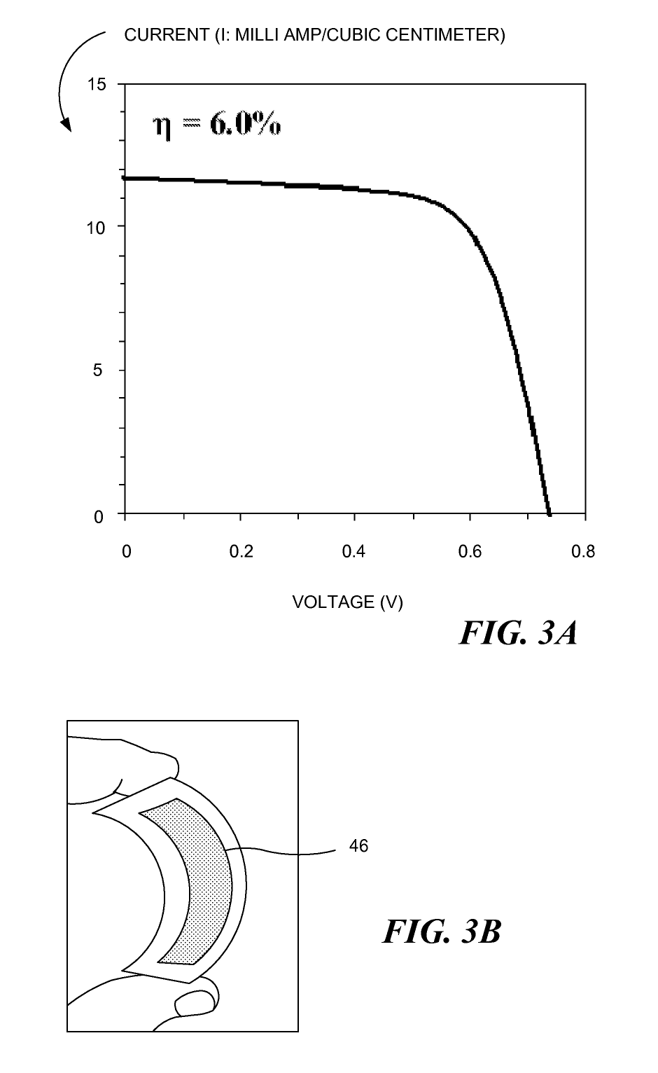

FIG. 3A graphically illustrates a current versus voltage curve of a PET-based DSSC specimen (4×4 mm² in size), which includes both an upper anti-reflecting coating, and a lower reflection layer, generally as discussed above. The PET-based DSSC specimen also includes the novel red dye, for interacting with red and IR light.

FIG. 3B schematically illustrates the PET-based DSSC specimen whose current versus voltage curve is shown in FIG. 3A, as the specimen is being bent between the fingers of a researcher. While FIG. 3B is an illustration rather than a photograph, the actual specimen can be flexed to the degree shown in the illustration. A portion 46 of the specimen is red in color, due to the novel red dye. Details of the novel red dye are provided below. Where the glass transparent conductive substrates of the specimen of FIG. 2B are replaced with a flexible transparent substrate (Pt-coated PET film) of the specimen of FIG. 3B, the observed PCE was close to 6%. It should be understood that the concepts disclosed herein also encompass DSSCs including the novel red dye and flexible substrates that employ a different electrolyte, and which lack one or more of the top anti-reflective coating, and the lower reflective layer, and combinations and permutations thereof.

The flexible DSSC device of FIGS. 3A and 3B has been scaled up to a larger-sized DSSC device, having dimensions of 10×10 mm², with a PCE of 4.6%. That larger device itself can be further scaled up to still larger sizes.

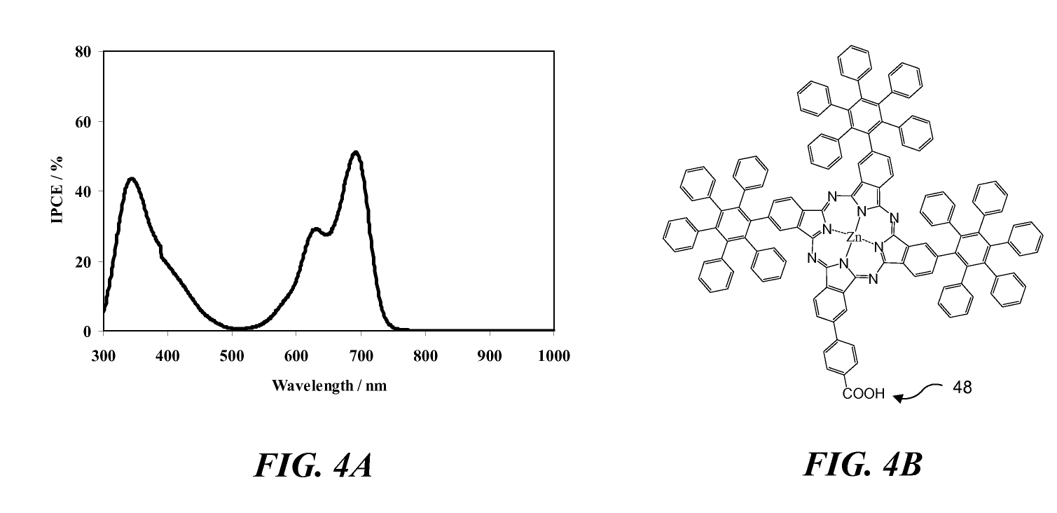

As noted above, a significant drawback of ruthenium-based sensitizers is their lack of absorption in the red region of the visible spectrum. Phthalocyanine dyes exhibit intense absorption in the red and near-IR regions. Another aspect of the concepts disclosed herein are novel phthalocyanine derivatives, which have absorption in the red and near-IR regions and which couple well to TiO₂. The incident photon-to-photon current efficiency (IPCE) of an empirical DSSC specimen using the phthalocyanine derivative as a sensitizer is 51% at 690 nm, as shown in FIG. 4A.

FIG. 4B schematically illustrates an exemplary novel phthalocyanine derivative, with a carboxyl group 48, which has been added to the normal phthalocyanine molecule. The novel phthalocyanine derivatives disclosed herein each include such a carboxylic acid group, whose function is to graft the sensitizer onto the semiconductor surface (the TiO₂), to provide intimate electrical coupling between the dye sensitizer and the TiO₂. Thus, the concepts disclosed herein encompasses phthalocyanine-based dyes, in which the phthalocyanine molecule has been modified by the addition of a carboxyl group. If desired, additional functions groups (i.e., in addition to the carboxyl group) can also be added to generate other derivatives.

As noted above, ruthenium-based sensitizer dyes work well for part of the visible light range, and the novel phthalocyanine derivatives disclosed herein work well with red and near-IR light. Unfortunately, if both dyes are incorporated into a single TiO₂-based working layer, charge interactions between the dyes actually reduce the effectiveness of the DSSC. While the phthalocyanine derivatives disclosed herein can be used alone (i.e., without the conventional ruthenium dyes), a DSSC including only the phthalocyanine derivatives would not make use of photons outside of the red and near-IR range.

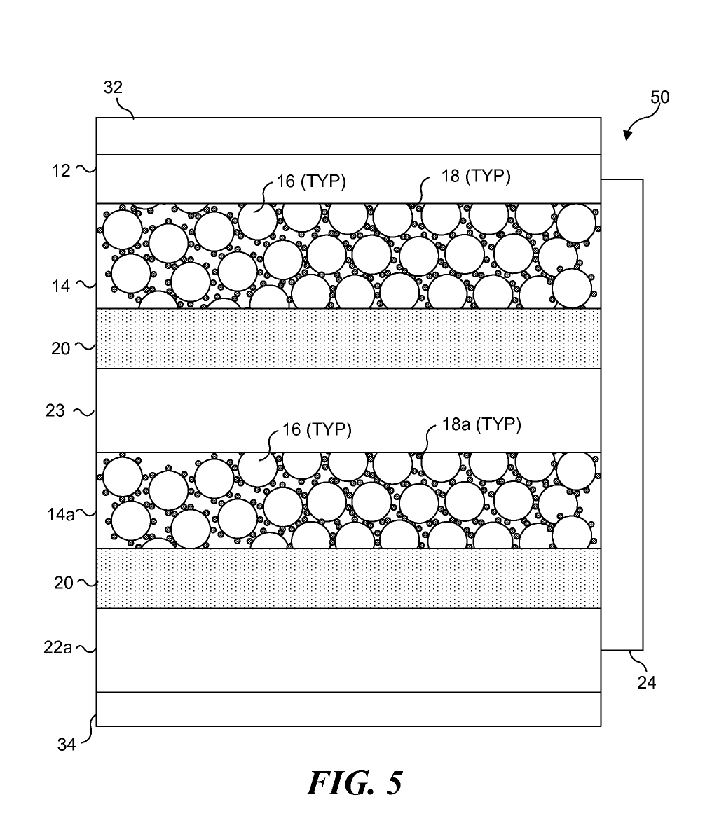

FIG. 5 schematically illustrates a DSSC including two different dye sensitizers incorporated into two different working layers, so that charge interactions between the different dye sensitizers do not impair operation of the resulting solar cell.

Referring to FIG. 5, a DSSC 50 includes upper transparent conductive substrate 12 coated with anti-reflective material 32. While the incorporation of anti-reflective material 32 is desirable, it should be understood that the concepts disclosed herein also encompass DSSCs including two different dye sensitizers, where no anti-reflective material 32 is employed. It should also be recognized that the upper transparent conductive substrate can be rigid (i.e., quartz or glass) or flexible (i.e., PET or some other polymer), generally as discussed above.

DSSC 50 includes both a working layer with TiO₂ and a ruthenium-based dye, and a working layer with TiO₂ and a phthalocyanine-based dye. As shown in FIG. 5, ruthenium working layer 14 (including semiconductor particles 16 coated with molecules 18 of the ruthenium dye sensitizer) is disposed closer to the transparent conductive substrate and phthalocyanine working layer 14a (including semiconductor particles 16 coated with molecules 18a of the novel red dye sensitizer) is disposed closest to reflective layer 34, although it should be understood that the relative positions of the working layers can be reversed. While the incorporation of reflective layer 34 is desirable, it should be understood that the concepts disclosed herein also encompass DSSCs including two different dye sensitizers, where no reflective layer 34 is employed.

An electrolyte layer 20 is disposed immediately adjacent to each working layer, to provide a source of electrons to replace electrons displaced from the dye sensitizer by interaction with photons. In some embodiments, the different electrolyte layers employ the same electrolyte. In other embodiments, a first electrolyte (optimized for interacting with the ruthenium working layer) is used with ruthenium working layer 14, and a second electrolyte (optimized for interacting with the phthalocyanine working layer) is used with phthalocyanine working layer 14a. Note that the second working layer from the top is disposed below the first electrolyte layer, so that the first electrolyte needs to be generally transparent (at least with respect to photons needed to interact with the dye in the second working layer). The second working layer needs to be generally transparent where reflective layer 34 is employed.

An additional transparent electrode 23 is disposed between the two different working layers. Again, the transparent electrode can employ a rigid substrate, or a flexible substrate, generally as discussed above. Finally, generally as discussed above, conductor 24 couples the upper transparent electrode with the lower counter electrode.

Thermoelectric Materials for Harvesting Energy from Waste Heat

Another aspect of the concepts disclosed herein is a set of new thermoelectric (TE) materials, each exhibiting a relatively high specific figure of merit (ZT/density). These materials include Mg₂Si, Mg₂Si—Ge, Mg₂Si—Bi, SiGe and their doped derivatives. TE modules based on these materials have been designed, and the module efficiencies predicted, based on various geometries. In the study, the objective function of a TE module was proposed, based on the specific figure of merit, the Clarke number, and the p- and n-pillar aspect ratio. For example, to achieve a larger load resistance, it is advantageous to employ as many pairs of p- and n-type TE pillars as practical.

Thermoelectric materials and TE modules are equally important as thermal energy harvesters for human carried equipment, equipment embedded in the human body (i.e., pacemakers, medical devices), and vehicles. For example, future air vehicles may incorporate TE modules for energy harvesting and cooling, in locations such as the leading edge of wings of a reentry vehicle, high power equipment such as radar and antennas, and engine exhaust.

Among the TE materials so far studied, the Mg₂Si system was found to have the highest specific figure of merit (i.e., ZT/weight of TE), for a typical use high temperature of 800 deg. K., as shown in Table 1 (which also provides the average Clarke number, indicating how abundant the material is on earth, based on the relative percentage of all elements; thus, the higher the Clarke number, the more abundant those elements are on earth, and more abundant materials are more likely to be available at a lower cost). In view of its specific ZT and higher Clark number, the Mg₂Si TE system appears to be the most favorable TE material.

TABLE 1
Comparison of specific figure of merit of various TE materials

| | |
|---|---|
| Specific figure of | Average |
| merit (ZT/Weight) | Clarke |

| Material | At 300 deg. K | At 800 deg. K | number |
|---|---|---|---|
| Mg₂Si | 0.051 /g | 0.359 /g | 14.83 |
| Bi₂Te₃ | 0.095 /g | 0.038 /g | 2.03e−5 |
| CsBi₄Te₆ | 0.084 /g | n/a | 2.6e−4 |
| AgPb₁₈SbTe₂₀ | 0.05 /g | 0.259 /g | 6.8e−3 |
| CoSb₃₋ₓTeₓ | 0.026 /g | 0.098 /g | 2.08e−3 |
| SiGe | n/a | 0.171 /g | 12.9 |

Current efforts are focused on designing TE modules based on Mg₂Si—Bi doped (n-type) and Mg₂Si—Ag doped (p-type). These designs consider the relative number of p- and n-type pillars, and the aspect ratio of the pillars, for a given set of boundary conditions (high temperature, low temperature, available surface area, etc.).

Among the TE materials listed in Table 2, Mg₂Si compounds and their derivatives (doped with Bi, and so on) with high specific ZT values were produced. SiGe TE materials, whose specific ZT values increase under higher use temperatures (up to 1000° C.), were also developed. The TE materials so developed were prepared as mechanical alloys (MA), followed by spark plasma sintering (SPS), from which n- and p-type TE specimens were removed for measurements of their TE properties (thermal conductivity, electrical conductivity and Seebeck coefficient as a function of RT—800° K).

The study also developed the concept of a nano composite based on single crystal SiGe, where nano-holes are formed into which another metal, such as Ge, is inserted, thereby forming a nano composite whose thermal conductivity is lowered, thus increasing the material's figure of merit value (ZT, which contains thermal conductivity in the denominator).

Although the concepts disclosed herein have been described in connection with the preferred form of practicing them and modifications thereto, those of ordinary skill in the art will understand that many other modifications can be made thereto within the scope of the claims that follow. Accordingly, it is not intended that the scope of these concepts in any way be limited by the above description, but instead be determined entirely by reference to the claims that follow.

The invention in which an exclusive right is claimed is defined by the following:

1. A dye sensitized solar cell (DSSC), comprising
(a) an upper anti-reflecting layer configured to reduce a number of photons that reflect off the upper surface of the DSSC;
(b) a working layer including a semiconductor and a dye sensitizer;
(c) a transparent electrode disposed between the working layer and the upper anti-reflecting layer;
(d) a counter electrode;
(e) a generally transparent electrolyte disposed between the working layer and the counter electrode; and
(f) a lower reflecting layer configured to direct photons passing through the counter electrode back into the DSSC.

2. The DSSC of claim 1, wherein the dye sensitizer comprises a phthalocyanine derivative.

3. The DSSC of claim 1, wherein the phthalocyanine derivative includes a carboxylic acid group to enhance an interaction between the semiconductor and the dye sensitizer.

4. The DSSC of claim 1, wherein the electrolyte is functional at temperatures below 0 deg. C.

5. The DSSC of claim 1, wherein the transparent electrode and the counter electrode comprise a flexible substrate.

6. A dye sensitized solar cell (DSSC), comprising
(a) an upper transparent electrode;
(b) a working layer including a semiconductor and a dye sensitizer, a relationship between the upper transparent electrode and the working layer being such that free electrons are able to move from the working layer to the upper transparent electrode;
(c) a counter electrode;
(d) an electrolyte disposed between the working layer and the counter electrode;
(e) a conductor coupling the upper transparent electrode and the counter electrode; and
(f) at least one additional element selected from a group of elements consisting of:
(i) an upper anti-reflecting layer configured to reduce a number of photons that reflect off the upper surface of the DSSC;
(ii) a lower reflecting layer configured to direct photons passing through the counter electrode back into the DSSC;
(iii) a phthalocyanine derivative dye sensitizer;
(iv) a relatively flexible and lightweight transparent substrate for implementing each of the upper transparent electrode and the counter electrode; and
(v) an electrolyte that remains functional at relatively low temperatures.

7. A thermoelectric material for harvesting energy from waste heat, the thermoelectric material comprising at least one element selected from a group of elements consisting of:
(a) Mg₂Si;
(b) a doped derivative of Mg₂Si;
(c) Mg₂Si—Ge;
(d) a doped derivative of Mg₂Si—Ge;
(e) Mg₂Si—Bi;
(f) a doped derivative of Mg₂Si—Bi;
(g) SiGe; and
(h) a doped derivative of SiGe.

8. The thermoelectric material of claim 7, wherein the thermoelectric material comprises a mechanical alloy bound together using spark plasma sintering.

9. A method for producing a thermoelectric material for harvesting energy from waste heat, comprising the steps of:
(a) preparing a mechanical alloy comprising at least two periodic elements, including a first periodic element that is a metalloid, and a second periodic element that is either a metalloid or a metal; and
(b) binding the mechanical alloy together using spark plasma sintering.

10. The method of claim 9, wherein the first periodic element is silicon.

11. The method of claim 10, wherein the second periodic element is germanium.

12. The method of claim 10, wherein the second periodic element is magnesium.

13. The method of claim 10, wherein the additional periodic element is bismuth.

14. The method of claim 10, wherein the additional periodic element is germanium.
